(19) United States
(12) Patent Application Publication
(10) Pub. No.: US 2012/0126144 A1
(43) Pub. Date: May 24, 2012

(54) LIGHT EMITTING DEVICE PACKAGE AND METHOD OF FABRICATING THE SAME

(75) Inventor: Kyu Tae Lee, Seoul (KR)

(73) Assignee: LG INNOTEK CO., LTD., Seoul (KR)

(21) Appl. No.: 13/246,282

(22) Filed: Sep. 27, 2011

(30) Foreign Application Priority Data
Nov. 19, 2010 (KR) 10-2010-0115881

(51) Int. Cl. F21K 2/00; H01L 21/77

(52) U.S. Cl. 250/462.1; 438/29

(57) ABSTRACT

Provided are a light emitting device package and a method of fabricating the light emitting device package. The light emitting device packages includes a body, a light emitting device disposed in the body, and a wavelength converting partwavelength converting part disposed on the light emitting device to convert a wavelength of light emitted from the light emitting device. The wavelength converting partwavelength converting part has a thickness decreasing in a direction away from a center of the light emitting device.

### CROSS-REFERENCE TO RELATED APPLICATION

This application claims the benefit under 35 U.S.C. §119 of Korean Patent Application No. 10-2010-0115881, filed on Nov. 19, 2010, which is hereby incorporated by reference in its entirety.

### BACKGROUND

The present disclosure relates to a light emitting device package and a method of fabricating the light emitting device package.

Light emitting diodes (LEDs) are semiconductor devices used in apparatuses such as home appliances, remote controllers, and large electronic boards for converting electricity into light such as ultraviolet rays, visible rays, and infrared rays.

LED light sources emitting very bright light are used for illumination devices or the like because LED light sources have good energy efficiency and require low maintenance costs owing to long lifespan. In addition, since LED light sources are durable to vibrations and impacts and do not include toxic materials such as mercury, existing incandescent lamps and fluorescent lamps are being replaced with LED light sources for the purposes of energy saving, environment protection, and cost reduction.

### BRIEF SUMMARY

Embodiments provide a light emitting device package emitting uniform color light and a method of fabricating the light emitting device package.

In one embodiment, a light emitting device packages includes: a body; a light emitting device disposed in the body; and a wavelength converting part disposed on the light emitting device to convert a wavelength of light emitted from the light emitting device, wherein the wavelength converting part has a thickness decreasing in a direction away from a center of the light emitting device.

In another embodiment, a light emitting device packages includes: a body; a light emitting device disposed in the body; and a wavelength converting part disposed on the light emitting device and having a convex shape, wherein the wavelength converting part has a center corresponding to an optical axis of the light emitting device.

In further another embodiment, there is provided a method of fabricating a light emitting device package, the method including: preparing a resin composition including a plurality of wavelength converting particles; placing the resin composition on a light emitting device; and hardening the resin composition using light emitted from the light emitting device.

The details of one or more embodiments are set forth in the accompanying drawings and the description below. Other features will be apparent from the description and drawings, and from the claims.

### BRIEF DESCRIPTION OF THE DRAWINGS

FIG. 1 is a perspective view illustrating a light emitting device package according to an embodiment.

FIG. 2 is a sectional view taken along line A-A′ of FIG. 1 according to an embodiment.

FIG. 3 is a sectional view illustrating a light emitting device according to an embodiment.

FIG. 4 is an enlarged sectional view illustrating the light emitting device and a wavelength converting part according to an embodiment.

FIG. 5 is an enlarged sectional view illustrating a light emitting device and a wavelength converting part according to another embodiment.

FIGS. 6 to 8 are views for explaining a method of fabricating a light emitting device package according to an embodiment.

### DETAILED DESCRIPTION

In the following description, it will be understood that when an element such as a body, a frame, an electrode, a layer (or film), or a pattern is referred to as being ‘on/above/over/upper’ another body, frame, electrode, layer (or film), or pattern, it can be directly on the other body, frame, electrode, layer (or film), or pattern, or one or more intervening bodies, frames, electrodes, layers (or films), or patterns may also be present. Further, it will be understood that when an element such as a body, a frame, an electrode, a layer (or film), or a pattern is referred to as being ‘under/below/lower’ another body, frame, electrode, layer (or film), or pattern, it can be directly under the other body, frame, electrode, layer (or film), or pattern, or one or more intervening bodies, frames, electrodes, layers (or films), or patterns may also be present. Therefore, meaning thereof should be judged according to the spirit of the present disclosure. Further, the reference about ‘on’ and ‘under’ each element will be made on the basis of drawings. Also, in the drawings, the sizes of elements may be exaggerated for clarity of illustration, and the size of each element does not entirely reflect an actual size.

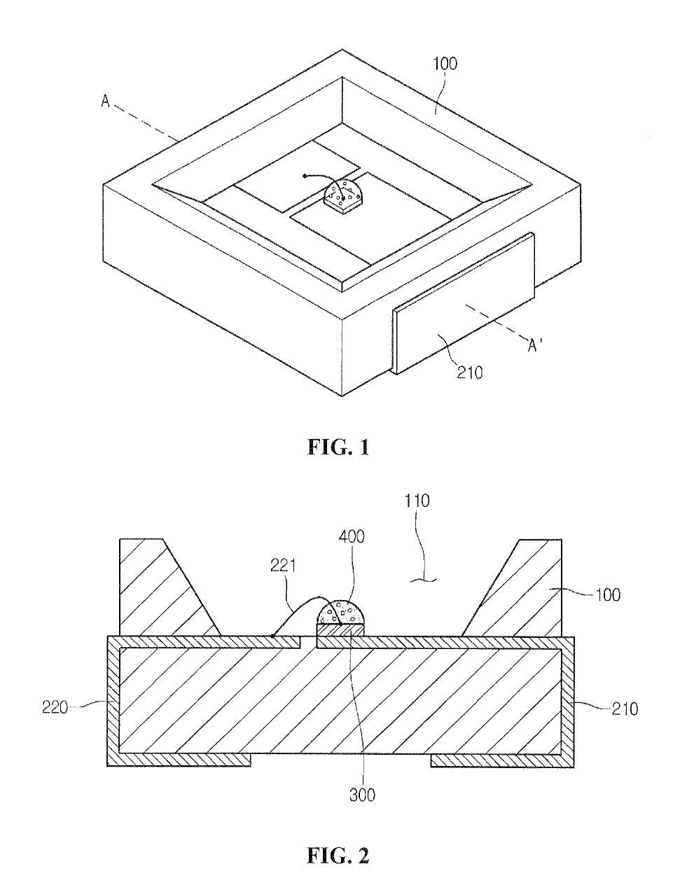

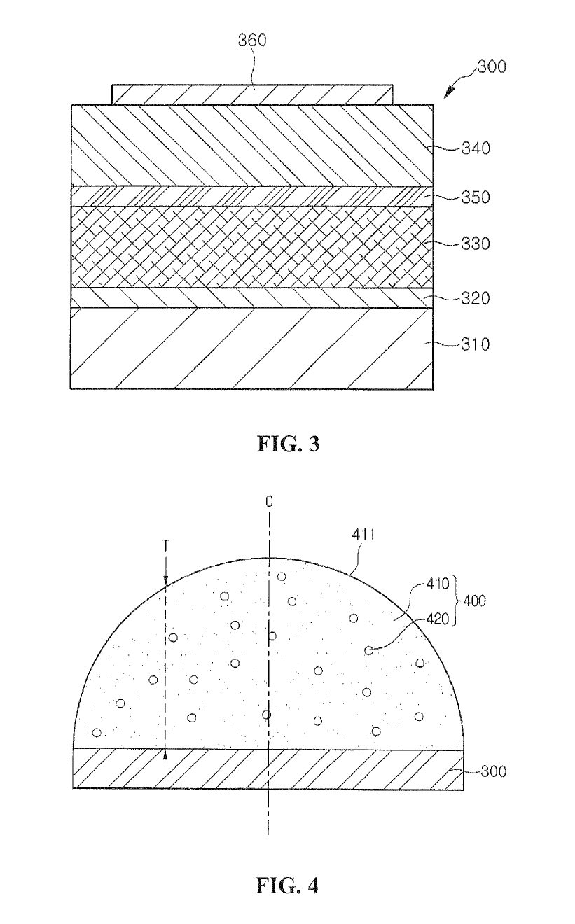

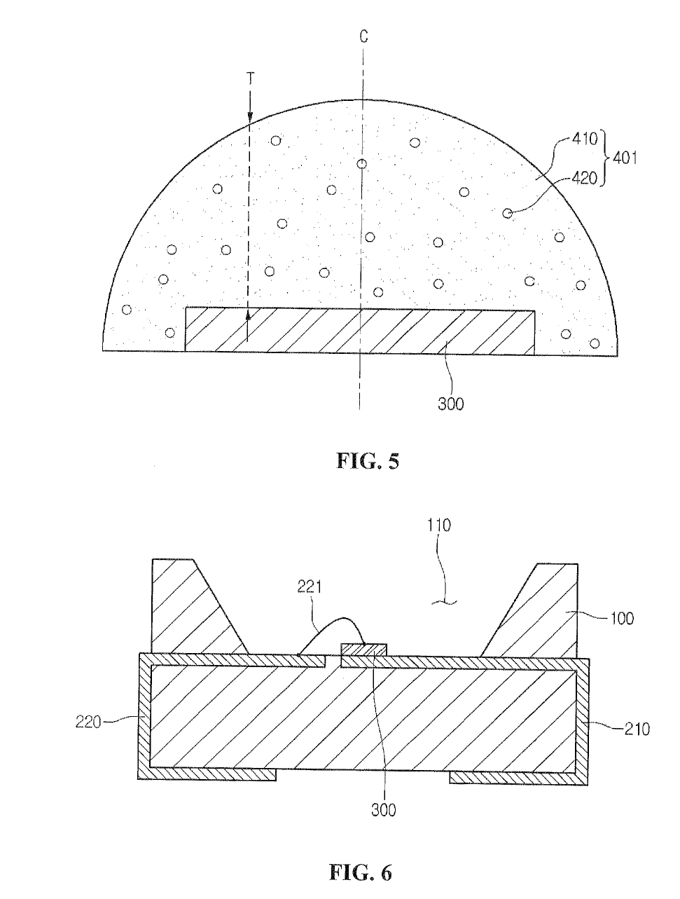

FIG. 1 is a perspective view illustrating a light emitting device package according to an embodiment. FIG. 2 is a sectional view taken along line A-A′ of FIG. 1. FIG. 3 is a sectional view illustrating a light emitting device according to an embodiment. FIG. 4 is an enlarged sectional view illustrating the light emitting device and a wavelength converting part according to an embodiment. FIG. 5 is an enlarged sectional view illustrating a light emitting device and a wavelength converting part according to another embodiment. FIGS. 6 to 8 are views for explaining a method of fabricating a light emitting device package according to an embodiment.

Referring to FIGS. 1 to 4, the light emitting device package includes a body 100, a plurality of lead electrodes 210 and 220, a light emitting device 300, and a wavelength converting part 400.

The body 100 accommodates the light emitting device 300 and the wavelength converting part 400. The body 100 supports the lead electrodes 210 and 220.

The body 100 may be formed of one of a resin material such as polyphthalamide (PPA), a ceramic material, a liquid crystal polymer (LCP), syndiotactic (SPS), polyphenylene ether (PPE), a silicon material. However, materials that can be used to form the body 100 are not limited thereto. The body 100 may be an one-piece part formed by an injection molding method. Alternatively, the body 100 may be formed by stacking a plurality of layers. The body 100 may include: a reflection part located above the lead electrodes 210 and 220 and having a cavity 110; and a body part located under or in the lead electrodes 210 and 220. However, the body 100 is not limited thereto.

The cavity 110 is formed in an upper part of the body 100, and the topside of the cavity 110 is opened. For example, the cavity 110 may be formed by patterning, punching, cutting, or etching the body 100. When fabricating the body 100, the cavity 110 may be formed by using a metal mold having a shape corresponding to the cavity 110.

The cavity 110 may have a cup shape or a concave vessel shape. The topside of the cavity 110 may have a circular shape or a polygonal shape. However, the cavity 110 is not limited thereto.

Lateral surfaces of the cavity 110 may be oblique or vertical to the bottom surface of the cavity 110 according to the light emitting angle of the light emitting device 300.

A highly reflective material such as white photo solder resist (PSR) ink, silver (Ag), or aluminum (Al) may he coated on or applied to the lateral surfaces of the cavity 110 so as to increase the light emitting efficiency of the light emitting device 300.

The lead electrodes 210 and 220 may be formed as lead frames. However, the lead electrodes 210 and 220 are not limited thereto.

The lead electrodes 210 and 220 are disposed in the body 100. The lead electrodes 210 and 220 are arranged on the bottom surface of the cavity 110 and are spaced apart from each other. Outer sides of the lead electrodes 210 and 220 may be exposed to the outside of the body 100.

Ends of the lead electrodes 210 and 220 may he disposed on a side of the cavity 110 or a side of the body 100 opposite to the cavity 110.

The lead electrodes 210 and 220 may be formed as lead frames when the body 100 is fabricated by injection molding. The lead electrodes 210 and 220 may be a first lead electrode 210 and a second lead electrode 220.

The first and second lead electrodes 210 and 220 are spaced apart from each other. The first and second lead electrodes 210 and 220 are electrically connected to the light emitting device 300.

The light emitting device 300 includes at least one light emitting diode chip. For example, the light emitting device 300 may include a color light emitting diode chip or an UV light emitting diode chip.

The light emitting device 300 may be a vertical light emitting diode chip. As shown in FIG. 3, the light emitting device 300 may include a conductive substrate 310, a reflection layer 320, a first conductive type semiconductor layer 330, a second conductive type semiconductor layer 340, an active layer 350, and a second electrode 360.

The conductive substrate 310 is formed of a conductive material. The conductive substrate 310 supports the reflection layer 320, the first conductive type semiconductor layer 330, the second conductive type semiconductor layer 340, the active layer 350, and the second electrode 360.

The conductive substrate 310 is connected to the first conductive type semiconductor layer 330 through the reflection layer 320. That is, the conductive substrate 310 is a first electrode through which an electrode signal can be applied to the first conductive type semiconductor layer 330.

The reflection layer 320 is disposed on the conductive substrate 310. Light emitted from the active layer 350 is reflected upward by the reflection layer 320. The reflection layer 320 is conductive. Thus, the conductive substrate 310 can be connected to the first conductive type semiconductor layer 330 through the reflection layer 320. The reflection layer 320 may be formed of a metal such as silver (Ag) and aluminum (Al).

The first conductive type semiconductor layer 330 is disposed on the reflection layer 320. The first conductive type semiconductor layer 330 has a first conductive type. The first conductive type semiconductor layer 330 may be an n-type semiconductor layer. For example, the first conductive type semiconductor layer 330 may be an n-type GaN layer.

The second conductive type semiconductor layer 340 is disposed above the first conductive type semiconductor layer 330. The second conductive type semiconductor layer 340 faces the first conductive type semiconductor layer 330. The second conductive type semiconductor layer 340 may be a p-type semiconductor layer. For example, the second conductive type semiconductor layer 340 may be a p-type GaN layer.

The active layer 350 is disposed between the first conductive type semiconductor layer 330 and the second conductive type semiconductor layer 340. The active layer 350 has a single quantum well structure or a multi quantum well structure. The active layer 350 may have periods of InGaN well layer and AlGaN barrier layer, or periods of InGaN well layer and GaN barrier layer. The materials of the active layer 350 may be changed according to a desired wavelength of light, such as blue wavelength light, red wavelength light, and green wavelength light.

The second electrode 360 is disposed on the second conductive type semiconductor layer 340. The second electrode 360 is connected to the second conductive type semiconductor layer 340.

Alternatively, the light emitting device 300 may be a horizontal light emitting diode. In this case, an additional line may be necessary for connecting the light emitting device 300 and the first lead electrode 210.

The light emitting device 300 may be connected to the first lead electrode 210, for example, through a bump. The light emitting device 300 may be connected to the second lead electrode 220 through a wire 221. Alternatively, the light emitting device 300 may be disposed directly on the first lead electrode 210.

However, the light emitting device 300 is not limited thereto. For example, the light emitting device 300 may be connected to the first and second lead electrodes 210 and 220 by wire bonding, die bonding, or flip bonding.

As shown in FIGS. 2 and 4, the wavelength converting part 400 is disposed on the light emitting device 300. In detail, the wavelength converting part 400 may be disposed directly on the top surface of the light emitting device 300. In more detail, the wavelength converting part 400 may be disposed only on the top surface of the light emitting device 300. Thus, when viewed from the topside, the outer line of the wavelength converting part 400 may coincide with the outer line of the light emitting device 300 or may be within the outer line of the light emitting device 300.

Alternatively, as shown in FIG. 5, the wavelength converting part 400 may cover the top surface and lateral surface of the light emitting device 300. That is, the wavelength converting part 400 may entirely cover the light emitting device 300 and may make contact with the first and second lead electrodes 210 and 220 and the body 100. That is, the wavelength converting part 400 may have a horizontal area greater than that of the light emitting device 300.

In this case, light emitted from the lateral surface of the light emitting device 300 may be effectively changed in wavelength by the wavelength converting part 400.

The wavelength converting part 400 changes the wavelength of incident light. In detail, the wavelength converting part 400 may change the color of light emitted from the light emitting device 300.

For example, blue light emitted from the light emitting device 300 may be converted into green light and red light by the wavelength converting part 400. For example, the wavelength converting part 400 may convert a portion of blue light into green light having a wavelength in the range from about 520 nm to about 560 nm and the other portion of the blue light into red light having a wavelength in the range from about 630 nm to about 660 nm.

In addition, ultraviolet light emitted from the light emitting device 300 may be converted into blue, green, and red light by the wavelength converting part 400. For example, the wavelength converting part 400 may convert a portion of ultraviolet light into blue light having a wavelength in the range from about 430 nm to about 470 nm, another portion of the ultraviolet light into green light having a wavelength in the range from about 520 nm to about 560 nm, and the other portion of the ultraviolet light into red light having a wavelength in the range from about 630 nm to about 660 nm.

Thus, white light can be obtained from light passed through the wavelength converting part 400 and light changed by the wavelength converting part 400. In other words, white light can be output upwardly by combining blue light, green light, and red light.

The wavelength converting part 400 includes a host 410 and a plurality of wavelength converting particles 420.

The host 410 is a main component of the wavelength converting part 400. The host 410 may be formed by hardening a photocurable resin composition 401. The host 410 includes a photopolymer which is a photocurable resin.

The host 410 is transparent and has relatively low oxygen permeability. For example, the photopolymer of the host 410 may be a silicon resin, an epoxy resin, or polycarbonate.

The wavelength converting particles 420 are uniformly dispersed in the host 410. The wavelength converting particles 420 change the wavelength of light emitted from the light emitting device 300. The wavelength converting particles 420 receive light emitted from the light emitting device 300 and change the wavelength of the light. For example, blue light emitted from the light emitting device 300 may be converted into green light and red light by the wavelength converting particles 420. For example, a portion of the wavelength converting particles 420 may convert blue light into green light having a wavelength in the range from about 520 nm to about 560 nm, and the other portion of the wavelength converting particles 420 may convert blue light into red light having a wavelength in the range from about 630 nm to about 660 nm.

In addition, ultraviolet light emitted from the light emitting device 300 may be converted into blue, green, and red light by the wavelength converting particles 420. For example, a portion of the wavelength converting particles 420 may convert ultraviolet light into blue light having a wavelength in the range from about 430 nm to about 470 nm, and another portion of the wavelength converting particles 420 may convert ultraviolet light into green light having a wavelength in the range from about 520 nm to about 560 nm. In detail, the other portion of the wavelength converting particles 420 may change ultraviolet light into red light having a wavelength in the range from about 630 nm to about 660 nm.

That is, if the light emitting device 300 is a blue light emitting diode (LED) that emits blue light, the wavelength converting particles 420 may include particles capable of converting blue light into green light, and particles capable of converting blue light into red light may. If the light emitting device 300 is an UV LED that emits ultraviolet light, the wavelength converting particles 420 may include particles capable of converting ultraviolet light into blue light; particles capable of converting ultraviolet light into green light, and particles capable of converting ultraviolet light into red light.

The wavelength converting particles 420 may be quantum dots (QDs). The quantum dots may include core nanocrystals and shell nanocrystals enclosing the core nanocrystals. The quantum dots may further include organic ligands bonded to the shell nanocrystals. The quantum dots may further include organic coating layers enclosing the shell nanocrystals.

The shell nanocrystals may have a multilayer structure. The shell nanocrystals are formed on the surfaces of the core nanocrystals. In the quantum dots, the wavelength of light incident to the core nanocrystals may be increased by the shell nanocrystals for improving optical efficiency.

The quantum dots may include at least one of a group II compound semiconductor, a group III compound semiconductor, and a group V compound semiconductor. In detail, the core nanocrystals may include Cdse, InGaP, CdTe, CdS, ZnSe, ZnTe, ZnS, HgTe, or HgS. The shell nanocrystals may include CuZnS, CdSe, CdTe, CdS, ZnSe, ZnTe, ZnS, HgTe, or HgS. The quantum dots may have a diameter in the range from 1 nm to 10 nm.

The wavelength of light from the quantum dots can be adjusted by varying the size of the quantum dots or the molar ratio of a molecular cluster compound and a nanoparticle precursor when forming the quantum dots. The organic ligands may include pyridine, mercapto alcohol, thiol, phosphine, and phosphine oxide. After the quantum dots are formed, the quantum dots may be unstable. Thus, the organic ligands are used to stabilize the quantum dots. After the quantum dots are formed, dangling bonds are present around the quantum dots, which may make the quantum dots unstable. Non-bonded ends of the organic ligands are bonded to the dangling bonds, and thus the quantum dots can be stabilized.

If the size of the quantum dots is smaller than the Bohr radius of excitons formed by electrons and holes excited by, for example, light or electricity, quantum confinement effect occurs. Then, the quantum dots have intermittent energy levels, and the energy gap of the quantum dots is varied. In addition, charges are confined in the quantum dots so that high light emitting efficiency can be obtained.

Unlike general fluorescent dyes, the fluorescence wavelength of the quantum dots is varied according to the size of the quantum dots. That is, as the size of the quantum dots is decreased, the wavelength of light from the quantum dots is shortened. That is, light having a desired wavelength such as visible light can be obtained by adjusting the size of the quantum dots. The extinction coefficient of the quantum dots is 100 to 1000 times that of general dyes, and the quantum yield of the quantum dots is very high. Thus, intensive fluorescent light can be obtained using the quantum dots.

The quantum dots may be prepared by a wet chemical method. In the wet chemical method, a precursor material is placed in an organic solvent to grow particles. In this way, the quantum dots can be synthesized by the wet chemical method.

Alternatively, the wavelength converting particles 420 may include a fluorescent material such as yttrium aluminum garnet (YAG), terbium aluminum garnet (TAG), or silicate.

As shown in FIG. 4, the wavelength converting part 400 has a convex shape. In detail, the wavelength converting part 400 includes a curved surface 411. For example, the wavelength converting part 400 may have a partial spherical shape. For example, the wavelength converting part 400 may have a semispherical shape.

The thickness (T) of the wavelength converting part 400 may decrease as it goes away from the center (C) of the light emitting device 300. That is, the thickness (T) of the wavelength converting part 400 may be maximal at the center (C) of the light emitting device 300. In other words, the thickness (T) of the wavelength converting part 400 may be minimal at the outer region of the light emitting device 300.

The center (C) of the light emitting device 300 may be on the optical axis of the light emitting device 300. That is, light emitted upward from the center (C) of the light emitting device 300 may be most intensive.

The center of the wavelength converting part 400 may correspond to the optical axis of the light emitting device 300. That is, the center of the wavelength converting part 400 may substantially coincide with the optical axis of the light emitting device 300. The center of the wavelength converting part 400 may correspond to the thickest (highest) region of the wavelength converting part 400. The thickness (T) of the wavelength converting part 400 may decrease as it goes away from the center (C) of the light emitting device 300.

Since the host 410 is a main component of the wavelength converting part 400, the shape of the wavelength converting part 400 may be substantially equal to the shape of the host 410. That is, the thickness of the host 410 may decrease as it goes away from the center (C) of the light emitting device 300.

The intensity of light emitted from the light emitting device 300 may be proportional to the length of optical paths of the wavelength converting part 400 along which the light propagates. That is, the thickness (T) of the wavelength converting part 400 is relatively thick at the center (C) of the light emitting device 300 where the intensity of light emitted from the light emitting device 300 is relatively high. Therefore, relatively intensive light emitted from the center (C) of the light emitting device 300 passes through the wavelength converting part 400 along a relatively long path.

On the other hand, the thickness (T) of the wavelength converting part 400 is relatively thin at the outer region of the light emitting device 300 where the intensity of light emitted from the light emitting device 300 is relatively low. Therefore, relatively weak light emitted from the outer region of the light emitting device 300 passes through the wavelength converting part 400 along a relatively short path.

Therefore, light passed through the wavelength converting part 400 may have uniform color regardless of positions along the wavelength converting part 400. That is, light passed through the wavelength converting part 400 may be uniform in each wavelength band.

For example, the light emitting device 300 may emit blue light, and the wavelength converting part 400 may convert the blue light into green light and red light. In this case, very bright blue light emitted from the center (C) of the light emitting device 300 passes through the relatively thick region of the wavelength converting part 400. Therefore, a large amount of the very bright light is converted into green and red light.

As a result, balance among blue, green, and red light may be properly maintained at the center region of the wavelength converting part 400, and thus desired white may be obtained.

Relatively low bright blue light emitted from the outer region of the light emitting device 300 passes through the relatively thin region of the wavelength converting part 400. Therefore, a small amount of the low bright light is converted into green and red light.

As a result, balance among blue, green, and red light may be properly maintained at the outer region of the wavelength converting part 400, and thus desired white may be obtained.

Thus, the light emitting device package of the embodiment can emit light having uniform color. Particularly, a yellow ring that occurs when blue light is insufficient may be reduced or not present at the outer region of the light emitting device package.

In addition, according to the current embodiment, the brightness of the light emitting device package can be improved owing to improved color uniformity.

FIGS. 6 to 8 are views for explaining a method of fabricating a light emitting device package according to an embodiment. The above description of the light emitting device package is incorporated in the following description of the method. That is, the above description of the light emitting device package is also applied to the following description of the method.

Referring to FIG. 6, a body 100 and lead electrodes 210 and 220 may be formed through an injection molding process. Next, a light emitting device 300 is bonded to the lead electrodes 210 and 220. The light emitting device 300 may be electrically connected to the lead electrodes 210 and 220 by a wire bonding method.

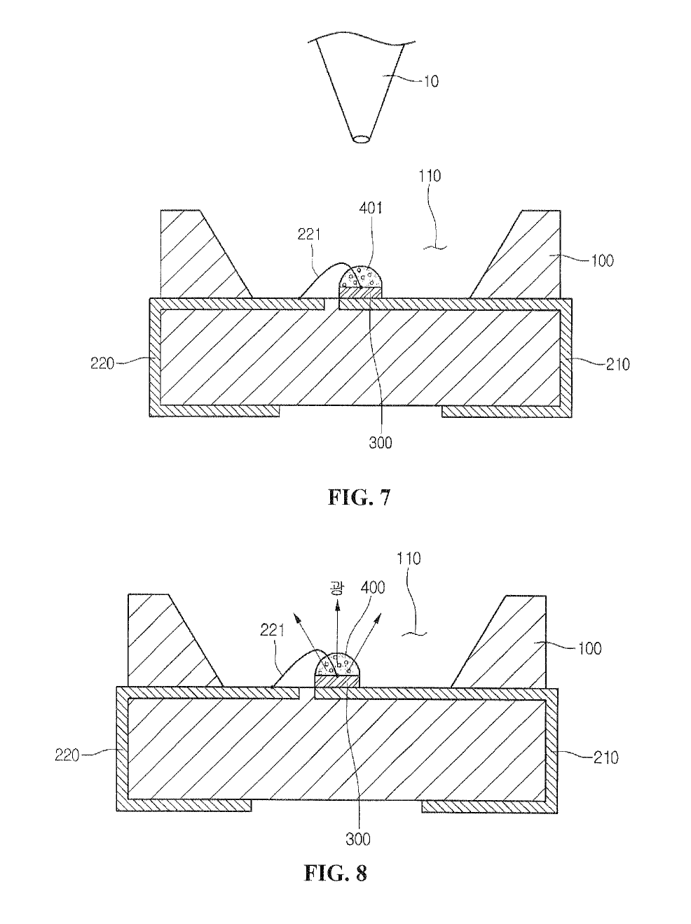

Referring to FIG. 7, a plurality of wavelength converting particles 420 are dispersed in a host material to form a photocurable resin composition 401.

A host 410 is formed by hardening the host material with ultraviolet light or blue light. The host material may be a polymer, an oligomer, or a monomer.

The host material is a transparent liquid. The host material may have high viscosity. The host material is a main component of the resin composition 401.

For example, the host material may be a silicon resin, a polyamic acid, a bisphenol A resin, an epoxy resin, or an acrylic resin. In addition, the host material may be a silicon monomer or an acrylic monomer.

Examples of the monomers include: 2-butoxyethyl acrylate, ethylene glycol phenyl ether acrylate, 2-butoxyethyl methacrylate, ethylene glycol phenyl ether methacrylate, 2-hydorxyethyl metal-acrylate, isodecyl methacrylate, phenyl methacrylate, bisphenol A propoxylate diacrylate, 1,3(1,4)-butandiol diacrylate, 1,6-hexandiol ethoxylate diacrylate, neopenyyl glycol diacrylate, ethylene glycol diacrylate, di(ethylene glycol) diacrylate, tetra ethylene glycol diacrylate, 1,3(1,4)-butandiol dimethacrylate, di urethane dimethacrylate, grycerol dimethacrylate, ethylene glycol dimethacrylate, di(ethylene glycol) dimethacrylate, tri(ethylene glycol) dimethacrylate, 1,6-bexandiol dimethacrylate, glycerol propoxylate triacrylate, pentaerythritol propoxylate triacrylate, ditrimetylolpropane tetraacrylate, and pentaerythritol tetra-acrylate.

The resin composition 401 may further include a photo curing initiator. When the photo curing initiator is exposed to light such as ultraviolet light, the photo curing initiator decomposes into radicals to initiate crosslinking and hardening of the photocurable resin composition 401. The kind and concentration of the photo curing initiator are properly selected according to factors such as the hardening rate and yellowing characteristics of the resin composition 401 and bonding characteristics of the resin composition 401 to a base material. If necessary, two kinds of photo curing initiators may be used.

Examples of the photo curing initiator include: α-hydroxyketone, phenylglyoxylate, benzildimethyl ketal, α-aminoketone, mono acyl phosphine, bis acyl phosphine, 2,2-dimethoxy-2-phenylacetophenone, and mixture thereof.

The resin composition 401 may include about 0.1 to 0.3 wt % of the photo curing initiator.

The resin composition 401 may further include a crosslinking agent. Examples of the crosslinking agent include: 1,6-Hexanediol diacrylate, dipropylene glycol diacrylate, neopentyl glycol diacrylate, trimethylolpropane triacrylate, ethoxylated trimethylolpropane triacrylate, trimethylolpropane trimethacrylate, pentaerythritol tetraacrylate, dipentacrylthritol hexaacrylate, vinyltriethoxysilane, vinyltrimethoxysilane, vinyl-tris-(2-methoxyethoxy) silane, and vinylmethyldimethoxysilnae.

The resin composition 401 is ejected to the light emitting device 300 through a process such as an inkjet process suing a nozzle.

Referring to FIG. 8, the resin composition 401 ejected on the light emitting device 300 may be hardened by light emitted from the light emitting device 300. At this time, the light emitting device 300 may be operated by an electric signal input through lead electrodes 210 and 220.

A portion of the resin composition 401 receiving relatively intensive light from the light emitting device 300 is rapidly and largely hardened rapidly and largely, and a portion of the resin composition 401 receiving less intensive light from the light emitting device 300 is slowly and less hardened.

At this time, a non-hardened portion of the resin composition 401 may flow to the portion of the resin composition 401 receiving relatively intensive light, and thus the portion of the resin composition 401 may be hardened more largely. Thus, a wavelength converting part 400 can be formed in a manner such that the wavelength converting part 400 is thick at a portion receiving intensive light and relatively thin at a portion receiving relatively weak light. That is, the resin composition 401 may be largely hardened at a portion around the optical axis of the light emitting device 300.

For example, light emitted from the light emitting device 300 may be relatively intensive at a center portion of the light emitting device 300 (a portion corresponding to the optical axis of the light emitting device 300) and may be less intensive at an outer portion of the light emitting device 300. In this case, the thickness (T) of the wavelength converting part 400 may decrease as it goes away from the center (C) of the light emitting device 300.

Alternatively, light emitted from the light emitting device 300 may be relatively intensive at an outer portion of the light emitting device 300 and may be less intensive at a center portion of the light emitting device 300. In this case, the thickness (T) of the wavelength converting part 400 may increase as it goes away from the center (C) of the light emitting device 300.

The light emitting device package of the current embodiment may be relatively using a hydrophilic or hydrophobic thin film.

For example, if a hydrophilic resin composition is used, the entire inside of a cavity 110 of the body 100 may be surface-treated so that the inside of the cavity 110 may he hydrophobic. Then, a hydrophilic thin film may be formed only on a region of the inside of the cavity 110 where a wavelength converting part will be disposed.

Thereafter, the resin composition is ejected on the region where the hydrophilic thin film is disposed. Then, the ejected resin composition becomes convex owing to the different surface characteristic between the hydrophilic thin film and the hydrophobic inside of the cavity 110.

Next, the convex resin composition may be entirely exposed to light such as ultraviolet light to form a convex wavelength converting part.

Alternatively, if a hydrophobic resin composition is used, the entire inside of the cavity 110 of the body 100 may be surface-treated so that the inside of the cavity 110 may be hydrophilic. Then, a hydrophobic thin film may be formed only on a region of the inside of the cavity 110 where a wavelength converting part will be disposed.

Thereafter, the resin composition is ejected on the region where the hydrophobic thin film is disposed. Then, the ejected resin composition becomes convex owing to the different surface characteristic between the hydrophobic thin film and the hydrophilic inside of the cavity 110.

Next, the convex resin composition may he entirely exposed to light such as ultraviolet light to form a convex wavelength converting part.

In this way, a light emitting device package capable of emitting light uniform color can be fabricated by the fabricating method of the current embodiment.

According to the embodiments, the wavelength converting part of the light emitting device package decreases in thickness as it goes away from the center of the light emitting device. Light emitted from the light emitting device is most intensive at the center of the light emitting device and becomes weaker as it goes away from the center of the light emitting device.

Since the thickness of the wavelength converting part is maximal at the center of the light emitting device, the amount of light changed by the wavelength converting part can be proportional to the intensity of the light. That is, bright light may pass through the thick region of the wavelength converting part, and less bright light may pass through the thin region of the wavelength converting part.

Therefore, the wavelength converting part can change light emitted from the light emitting device so that the light can have uniform color. That is, according to the embodiments, the light emitting device package can emit light having uniform color.

The wavelength converting part may be formed of a material such as a photocurable resin composition and hardened by light emitted from the light emitting device. That is, the wavelength converting part may be formed by hardening a photocurable resin composition by light emitted from the light emitting device.

Thus, the thickness of the wavelength converting part can be maximal at a portion close to the optical axis of the light emitting device. That is, the thickness of the wavelength converting part can be maximal at a portion receiving light most intensively. That is, according to the method of fabricating the light emitting device package, the thickness of the wavelength converting part can be automatically decreased in a direction away from the optical axis of the light emitting device without performing any additional process.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should he understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A light emitting device packages comprising:
a body;
a light emitting device disposed in the body; and
a wavelength converting partwavelength converting part disposed on the light emitting device to convert a wavelength of light emitted from the light emitting device,
wherein the wavelength converting partwavelength converting part has a thickness decreasing in a direction away from a center of the light emitting device.

2. The light emitting device package according to claim 1, wherein wavelength converting partwavelength converting part comprises a curved surface.

3. The light emitting device package according to claim 1, wherein the wavelength converting partwavelength converting part has a partial spherical shape.

4. The light emitting device package according to claim 3, wherein the wavelength converting partwavelength converting part has a semispherical shape.

5. The light emitting device package according to claim 1, wherein the wavelength converting partwavelength converting part covers top and lateral surfaces of the light emitting device.

6. The light emitting device package according to claim 1, wherein the wavelength converting partwavelength converting part is disposed only on a top surface of the light emitting device.

7. The light emitting device package according to claim 1, wherein wavelength converting partwavelength converting part comprises:
a host disposed on the light emitting device; and
wavelength converting partwavelength converting particles dispersed in the host,
wherein the host has a thickness decreasing in a direction away from the center of the light emitting device.

8. The light emitting device package according to claim 7, wherein the light emitting device emits blue light, and the wavelength converting partwavelength converting particles convert the blue light into green light and red light.

9. The light emitting device package according to claim 7, wherein the host comprises a photo curing initiator and a photocurable monomer.

10. A light emitting device packages comprising:
a body;
a light emitting device disposed in the body; and
a wavelength converting partwavelength converting part disposed on the light emitting device and having a convex shape,
wherein the wavelength converting partwavelength converting part has a center corresponding to an optical axis of the light emitting device.

11. The light emitting device package according to claim 10, wherein the wavelength converting partwavelength converting part has a thickness decreasing in a direction away from the optical axis of the light emitting device.

12. The light emitting device package according to claim 10, wherein an outer line of the wavelength converting partwavelength converting part coincides with an outer line of the light emitting device or is disposed within the outer line of the light emitting device.

13. The light emitting device package according to claim 10, wherein the wavelength converting partwavelength converting part covers a lateral surface of the light emitting device.

14. A method of fabricating a light emitting device package, the method comprising:
preparing a resin composition comprising a plurality of wavelength converting partwavelength converting particles;
placing the resin composition on a light emitting device; and
hardening the resin composition using light emitted from the light emitting device.

15. The method according to claim 14, wherein the light emitting device is disposed in a body,
the light emitting device and the resin composition have a first surface characteristic, and
the body has a second surface characteristic different from the first surface characteristic.

16. The method according to claim 15, wherein the light emitting device and the resin composition are hydrophilic, and the body is hydrophobic.

17. The method according to claim 14, wherein as a result of hardening of the resin composition, a wavelength converting partwavelength converting part is formed on the light emitting device, and the wavelength converting partwavelength converting part has a thickness decreasing in a direction away from an optical axis of the light emitting device.

18. The method according to claim 14, wherein the resin composition comprises a photocurable resin.

19. The method according to claim 1.4, wherein the resin composition is disposed on a top surface of the light emitting device.
